(19) United States
(12) Patent Application Publication
(10) Pub. No.: US 2007/0216264 A1
(43) Pub. Date: Sep. 20, 2007

(54) Multilayer piezoelectric element

(75) Inventors: Masahito Furukawa, Tokyo (JP); Norimasa Sakamoto, Tokyo (JP)

Correspondence Address: KANESAKA BERNER AND PARTNERS LLP, 1700 DIAGONAL RD, SUITE 310, ALEXANDRIA, VA, 22314-2848, US

(73) Assignee: TDK Corporation, Tokyo (JP)

(21) Appl. No.: 11/716,700

(22) Filed: Mar. 12, 2007

(30) Foreign Application Priority Data
Mar. 20, 2006 (JP) 2006-077747

(51) Int. Cl. H01L 41/083

(52) U.S. Cl. 310/366; 310/328

(57) ABSTRACT

A multilayer piezoelectric element has a plurality of piezoelectric layers and a plurality of internal electrodes stacked alternately. The piezoelectric layers contain an oxide containing an alkali metal element and niobium or bismuth. The internal electrodes are formed of a base metal that is preferably copper or copper alloy. The oxide contains niobium and an alkali metal element that preferably includes sodium, potassium and lithium. Otherwise, the oxide contains bismuth and an alkali metal element that preferably includes sodium or potassium.

### BACKGROUND OF THE INVENTION

1. Field of the Invention

The present invention relates to a multilayer piezoelectric element usable as an actuator or a transformer, such as an inkjet printer, an actuator for fuel injection or a piezoelectric transformer, for example.

2. Description of the Prior Art

A piezoelectric actuator, one of piezoelectric elements, utilizes a piezoelectric phenomenon that generates mechanical distortion and stress when undergoing an electric field as a driving source. This actuator has characteristic features in that a minute displacement can be obtained with high precision and that the stress generated is large and is used for positioning a precise tool or an optical device, for example. As piezoelectric porcelain, lead zirconium titanate (PZT) having an excellent piezoelectric property has heretofore been put to practical use. However, since the PZT contains a great amount of lead, an adverse effect extending to a global environment including elution of lead by acid fallout has been in question. For this reason, there has been a great demand for developing lead-free piezoelectric porcelain as a substitute for the PZT.

As the lead-free piezoelectric porcelain, that containing barium titanate (BaTiO₃) as a principal component can be cited (refer, for example, to JP-HEI 2-159079). This piezoelectric porcelain is excellent in relative permittivity εr and electromechanical coupling factor kr and has promise as a piezoelectric material for an actuator.

However, the lead-free piezoelectric porcelain poses problems in that it has low piezoelectric characteristics as compared with lead-based piezoelectric porcelain and that it cannot obtain a sufficiently large displacement generated. In addition, in the piezoelectric porcelain containing barium titanate as a principal component, since the barium titanate has a low Curie temperature of about 120° C., there is also a problem in that the range of temperature usable is limited to 100° C. or less.

On the other hand, as another lead-free piezoelectric porcelain, that containing lithium sodium potassium niobate as a principal component has been known to the art (refer, for example, to JP-A SHO 49-125900 and JP-B SHO 57-6713). Since this piezoelectric porcelain has a high Curie temperature of 350° C. or more and is excellent in electromechanical coupling factor kr, it has been expected as a substitute for a lead-based piezoelectric material. Furthermore, a composite of potassium sodium niobate and tungsten bronze-based oxide (refer to JP-A HEI 9-165262) and a composite of the composite cited here and barium titanate (refer to JP-A 2002-23411) have been reported.

Moreover, as lead-free piezoelectric porcelain, that containing perovskite-structure oxide that contains Bi has been known to the art. JP-A HEI 11-171643, for example, discloses a piezoelectric porcelain composition represented by [Bi_{0.5}(Na₁₋ₓKₓ)_{0.5}]TiO₃.

Incidentally, piezoelectric layers formed of a piezoelectric porcelain composition and having an internal electrode sandwiched between them are stacked into a multilayer, the multilayer is at an advantage in that a displacement generated can be made large and optionally be adjusted depending on the number of layers to be stacked. A noble metal element, such as palladium (Pd), platinum (Pt), gold (Au) or silver (Ag), is generally used as a material for the internal electrode of a multilayer piezoelectric element. Among other noble metal elements enumerated above, attention has been paid to a silver-palladium (Ag—Pd) alloy because the alloy is a relatively inexpensive material in spite of the fact that the alloy is composed of noble metals.

Since the piezoelectric layers formed of lead-free piezoelectric porcelain containing niobium (Nb) as described in the second to fifth mentioned prior art references and the internal electrodes formed of a silver-palladium (Ag—Pd) alloy are alternately stacked into a multilayer piezoelectric element, however, the niobium (Nb) in the piezoelectric layers is allowed to react with the silver (Ag) in the internal electrodes to deteriorate the piezoelectric characteristics. This is problematic.

Also in the multilayer piezoelectric element, a combination of a piezoelectric layer formed of lead-free piezoelectric porcelain containing bismuth (Bi) as disclosed in the sixth mentioned prior art reference with an internal electrode formed of silver-palladium (Ag—Pd) alloy induces a reaction between the bismuth (Bi) in the piezoelectric layer and the palladium (Pd) in the internal electrode to deteriorate the piezoelectric characteristics. This is also problematic.

The present invention has been accomplished in view of the problems described above, and the object thereof is to provide a multilayer piezoelectric element capable of acquiring a large displacement generated and excellent from the standpoint of the environmental conservation.

### SUMMARY OF THE INVENTION

To attain the above object, the present invention provides a multilayer piezoelectric element comprising a plurality of piezoelectric layers each formed of an oxide containing an alkali metal element and niobium (Nb) or bismuth (Bi) and a plurality of internal electrodes each formed of a base metal, the layers and electrodes being alternately stacked.

In the multilayer piezoelectric element having the above configuration, since the oxide containing an alkali metal element and niobium (Nb) or bismuth (Bi) is used for the piezoelectric layers and since the base metal difficult to react with niobium (Nb) and bismuth. (Bi) is used for the internal electrodes, the piezoelectric characteristics are not deteriorated to acquire a large displacement.

The internal electrodes are preferably formed of copper (Cu) or copper (Cu) alloy. When the piezoelectric layers and internal electrodes are to be fired simultaneously, in order to suppress oxidation of the base metal contained in the internal electrodes, it is necessary to control the firing atmosphere. Use of copper (Cu) or copper (Cu) alloy enables the firing atmosphere to be controlled easily as compared with use of other base metals, such as nickel (Ni).

When the oxide is that containing an alkali metal element and niobium (Nb), the niobium (Nb) preferably has tantalum substituted for part thereof accounting for 15 mol % or less. This makes it possible to obtain more excellent piezoelectric characteristics and to make a displacement generated larger.

When the oxide is that containing an alkali metal element and niobium (Nb), the piezoelectric layers preferably contain 1 mol % or less of a tungsten bronze-structure oxide containing an alkaline earth metal element and niobium (Nb). This makes it possible to obtain more excellent piezoelectric characteristics and to make a displacement generated larger.

When the oxide contains niobium (Nb), the piezoelectric layers preferably contain 15 mol % or less of a perovskite-structure oxide containing an alkaline earth metal element and at least one species selected. from the group consisting of titanium (Ti) and. zirconium (Zr). The piezoelectric layers containing the perovskite-structure oxide containing an alkaline earth metal element and at least one species selected from the group consisting of titanium (Ti) and zirconium (Zr) in addition to the tungsten bronze-structure oxide make it possible to further enhance the piezoelectric characteristics and to obtain a much larger displacement generated.

When the oxide is that containing an alkali metal element and bismuth (Bi), the piezoelectric layers preferably contain 15 mol % of a perovskite-structure oxide containing an alkaline earth metal and at least one species selected from the group consisting of titanium (Ti) and zirconium (Zr). This makes it possible to obtain more excellent piezoelectric characteristics and to make a displacement generated much larger.

According to the present invention, it is made possible to realize an inexpensive multilayer piezoelectric element not exhibiting any deterioration in piezoelectric characteristics resulting from a reaction of niobium (Nb) or bismuth (Bi) in piezoelectric layers with internal electrodes, but exhibiting a large displacement. Also according to the present invention, since the piezoelectric layers are free of lead, it is made possible to materialize a multilayer piezoelectric element excellent from the viewpoint of low-pollution properties, environment resistant properties and bionomics.

The above and other objects, characteristic features of the present invention will become apparent to those skilled in the art from the description to be given herein below with reference to the accompanying drawings.

### BRIEF DESCRIPTION OF THE DRAWING

FIG. 1 is a schematic cross section showing a multilayer piezoelectric element according to one embodiment of the present invention.

### DETAILED DESCRIPTION OF THE PREFERRED EMBODIMENT

An embodiment of the present invention will be described hereinafter in detail.

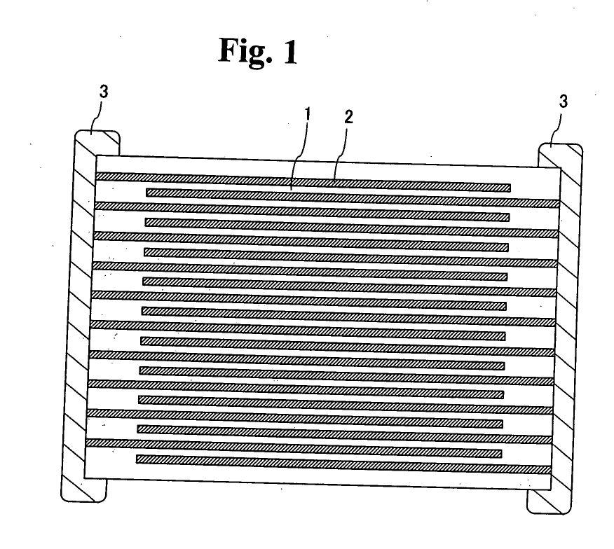

A multilayer piezoelectric element according to one embodiment of the present invention has, as shown in FIG. 1, for example, a plurality of piezoelectric layers 1 and a plurality of internal electrodes 2 stacked alternately. The internal electrodes 2 are extended alternately in the opposite directions and electrically connected at the extended opposite ends thereof to a pair of terminal electrodes (external electrodes) 3.

In the multilayer piezoelectric element according to the present embodiment, the internal electrode 2 is formed of a base metal. When the piezoelectric layer 1 contains an oxide containing an alkali metal element and niobium (Nb) or bismuth (Bi), use of an ordinary silver-palladium (Ag—Pd) alloy as an material for the internal electrodes of the multilayer piezoelectric element allows the material in the piezoelectric layer to react with the silver-palladium (Ag—Pd) alloy, thereby deteriorating the piezoelectric characteristics of the multilayer piezoelectric element. On the other hand, by forming the internal electrode of a base metal, it is made possible to use piezoelectric layers formed of an oxide containing an alkali metal element and niobium (Nb) or an oxide containing alkali metal element and bismuth (Bi) without deteriorating the piezoelectric characteristics. It is therefore possible to realize the provision of a multilayer piezoelectric element exhibiting a large displacement in spite of low production cost.

As the base metal of which the internal electrode is formed, copper (Cu), copper (Cu) alloy, nickel (Ni) and nickel (Ni) alloy can be cited. Among other base metals enumerated above, copper (Cu) or copper (Cu) alloy is preferable.

The thickness of the internal electrode is preferably in the range of around 0.5 μm to around 5 μm for example. When it is smaller than 0.5 μm the internal electrode will possibly be discontinued to bring about a failure to obtain a satisfactory piezoelectric characteristics (displacement), whereas when it is larger than 5 μm the stacked body will be greatly distorted when the number of layers stacked becomes large, thereby inducing cracks or other defects in the multilayer piezoelectric element produced by firing.

The piezoelectric layers of the multilayer piezoelectric element in the present embodiment contain an oxide containing an alkali metal element and niobium (Nb) or bismuth (Bi). That is to say, the piezoelectric layers contain at least one of two oxides, one containing an alkali metal element and niobium (Nb) and the other containing an alkali metal element and bismuth (Bi).

The optimal composition of the piezoelectric layer will vary depending on the case (1) where the piezoelectric layer contains an oxide containing an alkali metal element and niobium (Nb) or the case (2) where the piezoelectric layer contains an oxide containing an alkali metal element and bismuth (Bi). Therefore, the two cases will be described separately.

The case (1) will first be described. An oxide containing an alkali metal element and niobium (Nb) is a perovskite-structure oxide of A¹⁺B⁵⁺O₃ type. It is noted that the perovskite-structure oxide used in the present invention includes an ilmenite-structure oxide.

In the oxide containing an alkali metal element and niobium (Nb), sodium (Na), potassium (K) and lithium (Li) are preferably contained as the alkali metal elements, and tantalum (Ta) may be substituted for part of the niobium (Nb). The oxide containing an alkali metal element, niobium (Nb) and oxygen is represented by chemical formula (1) below, for example.
(Na _{1-x-y}KₓLi_{y})ₚ(Nb_{1-z}Ta_{z})O₃ (1)
wherein 0<x<1, 0≦y<1, 0≦z<1 and p is stoichiometrically 1. It is noted, however, that the value of p may be deviated from the stoichiometric value. It is also noted that the composition of oxygen is stoichiometrically determined and may be deviated from the stoichiometrical composition.

The content of potassium (K) in the alkali metal element preferably falls in the range of 10 mol % or more and 90 mol % or less. To be specific, “x” in chemical formula (1) preferably satisfies 0.1≦x≦0.9 in molar ratio. When the content of potassium (K) is unduly small, the relative permittivity εr, electromechanical coupling factor and displacement generated will not be able to be made sufficiently large, whereas when it is unduly large, firing will be difficult to perform because potassium is vigorously evaporated during the firing.

The content of lithium (Li) in the alkali metal element preferably falls in the range of 0 mol % or more and 15 mol % or less. To be specific,“y” in chemical formula (1) preferably satisfies 0≦x≦0.15 in molar ratio. When the content of lithium (Li) is unduly large, the relative permittivity εr, electromechanical coupling factor and displacement generated will not be able to be made sufficiently large.

In addition, the amount of tantalum (Ta) to be substituted for part of niobium (Nb) preferably falls in the range of 0 mol % or more and 15 mol % or less based on the amount of the niobium. Therefore, “z” in chemical formula (1) preferably satisfies 0≦z≦0.15 in molar ratio. When the amount of tantalum (Ta) is unduly large, the Curie temperature will be lowered while the relative permittivity εr will be made high. Besides the tantalum (Ta), antimony (Sb) that is also a quinquevalent element may be substituted for part of niobium (Nb).

In chemical formula (1),“p” preferably falls in the range of 0.95 or more and 1.05 or less in molar ratio. When“p” is less than 0.95, the relative permittivity εr, electromechanical coupling factor kr and displacement generated will become small, whereas when it exceeds 1.05, the sintering density will be lowered to make the polarization difficult.

The piezoelectric layer is preferred to contain, in addition to the perovskite-structure oxide containing the alkali metal element and niobium (Nb), 1 mol % or less, based on the piezoelectric layer, of an oxide of tungsten bronze structure containing an alkaline earth metal element and niobium (Nb). As the alkaline earth metal element in the tungsten bronze-structure oxide, at least one species is selected preferably from the group consisting of magnesium (Mg), calcium (Ca), strontium (Sr) and barium (Ba). Tantalum (Ta) may be substituted for part of niobium (Nb) in the tungsten bronze-structure oxide. The tungsten bronze-structure oxide can be represented by chemical formula (2) below, for example.
M1(Nb_{1-w}Ta_{w})₂O₆ (2)
wherein M1 stands for an alkaline earth metal element and 0≦w<0.15. The compositional ratios of the element M1 , (Nb_{1-w}Ta_{w}) and oxygen are obtained stoichiometrically, but may be deviated from the stoichiometric compositions.

Incidentally, the ratio of niobium (Nb) to tantalum (Ta) in the tungsten bronze-structure oxide may be either identical with or different from that in the oxide containing the alkali metal element and niobium (Nb).

The total content of tantalum (Ta) in the oxide containing the alkali metal element and niobium (Nb) and the tungsten bronze-structure oxide is preferred to be 15 mol % or less based on the content of niobium (Nb). When the total content of tantalum (Ta) is unduly large, the Curie temperature will be lowered and the electromechanical coupling factor and displacement generated will become small as well.

Otherwise, the piezoelectric layer is preferred to contain 15 mol % or less of a perovskite-structure oxide containing an alkaline earth metal element and at least one of titanium (Ti) and zirconium (Zr). The perovskite-structure oxide containing the alkaline earth metal element and at least one of titanium (Ti) and zirconium (Zr) is preferably used in conjunction with the tungsten bronze-structure oxide. In this case, more excellent piezoelectric characteristics can be acquired.

As the alkaline earth metal element in the perovskite-structure oxide containing the alkaline earth metal element and at least one of titanium (Ti) and zirconium (Zr), at least one species selected from the group consisting of magnesium (Mg), calcium (Ca), strontium (Sr) and barium (Ba) is preferable. The perovskite-structure oxide containing the alkaline earth metal element and at least one of titanium (Ti) and zirconium (Zr) is represented by chemical formula (3) below, for example.
M2(TiᵥZr₁₋ᵥ)O₃ (3)
wherein M2 denotes an alkaline earth metal element. The compositional ratios of the alkaline earth metal element, titanium (Ti), zirconium (Zr) and oxygen (O) are stoichiometrically obtained, but may be deviated from the stoichiometrical compositions. The relation between the titanium (Ti) and zirconium (Zr) is satisfied with 0≦v≦1. The perovskite-structure oxide may further contain hafnium (Hf).

The ratios of the three kinds of oxides in the piezoelectric layer preferably satisfy the conditions of formula (4) below.
(1−m−n)A+mB+nC (4)
wherein A denotes a perovskite-structure oxide containing an alkali metal element and niobium, B a perovskite-structure oxide containing an alkaline earth metal element and at least one of titanium (Ti) and zirconium (Zr), C a tungsten bronze-structure oxide containing an alkaline earth metal element and niobium (Nb), and m and n molar ratios and satisfy 0≦m≦0.15 and 0≦n≦0.01, respectively. By setting the m and n to fall in the respective ranges, well-balanced high values of the characteristics of the relative permittivity εr, electromechanical coupling factor kr and displacement generated can be obtained.

When the piezoelectric layer contains as chief ingredients a perovskite-structure oxide containing an alkali metal element and niobium (Nb), a tungsten bronze-structure oxide and a perovskite-structure oxide containing alkaline earth metal element and at least one of titanium (Ti) and zirconium (Zr), it preferably contains an oxide containing at least one of a transition metal and a rare-earth metal as an accessory ingredient. The preferable content of the accessory ingredient is in the range of 0.1 mass % or more and 1 mass % or less based on the mass of the chief ingredients. This is because the sinterability can be enhanced to further enhance the piezoelectric characteristics. The oxide as the accessory ingredient can either exist in grain boundaries of the composition of the main ingredients or exist in a dispersed state in part of the composition of the main ingredients. Among other oxides, an oxide containing manganese (Mn) as the transition metal is preferable.

Incidentally, in order to enhance the piezoelectric property (displacement), mechanical quality factor (Qm), relative permittivity and reliability on various points, the oxide as the accessory ingredient may contain other plural elements in addition to manganese (Mn).

In order for the oxide serving as the accessory ingredient and containing manganese (Mn), for example, to be contained in the piezoelectric layer, manganese is caused to be contained in the form of manganese carbonate (MnCO₃) in the raw materials for forming a piezoelectric layer, thereby making it possible to stably perform the firing and polarization.

Next, the case where the piezoelectric layer contains an oxide containing an alkali metal element and bismuth (Bi) will be described in detail. The oxide containing an alkali metal element and bismuth (Bi) is a perovskite-structure oxide of A²⁺B⁴⁺O₃ type. In the oxide containing an alkali metal element and bismuth (Bi), preferably at least one of sodium (Na) and potassium (K) is contained as the alkali metal element.

The oxide containing an alkali metal element and bismuth (Bi) is represented by chemical formula (5) below, for example.
((Na₁₋ᵤKᵤ)_{0.5}Bi_{0.5})TiO₃ (5)
wherein u is preferably in the range of 0.01 or more and 0.40 or less

The piezoelectric layer containing an oxide containing an alkali metal element and bismuth (Bi) can assume two states, i.e. one state containing sodium bismuth titanate ((Na_{0.5}Bi_{0.5})TiO₃) that is a compound of rhombohedral perovskite structure and potassium bismuth titanate ((K_{0.5}Bi_{0.5})TiO₃) that is a compound of tetragonal perovskite structure and the other state containing a solid solution containing sodium bismuth titanate ((Na_{0.5}Bi_{0.5})TiO₃) that is a compound of rhombohedral perovskite structure and potassium bismuth titanate ((K_{0.5}Bi_{0.5})TiO₃ that is a compound of tetragonal perovskite structure. That is to say, the sodium bismuth titanate ((Na_{0.5}Bi_{0.5})TiO₃) that is a compound of rhombohedral perovskite structure and the potassium bismuth titanate ((K_{0.5}Bi_{0.5})TiO₃) that is a compound of tetragonal perovskite structure may be either in a solid-solution state or in an incomplete solid-solution state.

As a result, in part of the piezoelectric porcelain obtained, a crystallographic Morphotropic Phase Boundary (M.P.B.) is formed, thereby promising the enhancement of the piezoelectric characteristics. To be specific, it is promised that the piezoelectric characteristics including permittivity, electromechanical coupling factor or dielectric constant are enhanced as compared with one-gradient-based or two-gradient-based piezoelectric porcelain.

The sodium bismuth titanate has a rhombohedral perovskite structure in which sodium (Na) and bismuth (Bi) are disposed at the A-site thereof and titanium (Ti) at the B-site thereof. The composition thereof is represented by chemical formula (6) below, for example.
(Na_{0.5} Bi_{0.5})₅TiO_{S} (6)
wherein s is 1 in the case of the stoichiometrical composition, may be deviated from the stoichiometrical composition. When s is 1 or less, it is made possible to advantageously heighten the sinterability and piezoelectric characteristics as well. The compositions of sodium (Na), bismuth (Bi) and oxygen (O) are determined based on the stoichiometrical composition, but may be deviated from the stoichiometrical composition.

The potassium bismuth titanate has a tetragonal perovskite structure in which potassium (K) and bismuth (Bi) are disposed at the A-site thereof and titanium (Ti) at the B-site thereof. The composition thereof is represented by chemical formula (7) below, for example.
(K_{0.5} Bi_{0.5})ₜTiO₃ (7)
wherein t is 1 in the case of the stoichiometrical composition, may be deviated from the stoichiometrical composition. The compositions of potassium (K), bismuth (Bi) and oxygen (O) are determined based on the stoichiometrical composition, but may be deviated from the stoichiometrical composition.

In the compositional ratios in molar ratio of the sodium bismuth titanate ((Na_{0.5}Bi_{0.5})TiO₃) that is a compound of rhombohedral perovskite structure and potassium bismuth titanate ((K_{0.5}Bi_{0.5})TiO₃) that is a compound of tetragonal perovskite structure. That is to say, the sodium bismuth titanate ((Na_{0.5}Bi₅)TiO₃) that is a compound of rhombohedral perovskite structure, it is desirable that the compositional ratio of (K_{0.5}Bi_{0.5})TiO₃ be 40% or less. The compositional ratio exceeding 40% make the piezoelectric layer far from the crystallographic M.P.B., thereby deteriorating the piezoelectric characteristics. Incidentally, the compositional ratio used herein is based on the oxide, as a whole, containing the alkali metal element and bismuth (Bi) in an incomplete solid-solution state or in a solid-solution state.

When the piezoelectric layer contains an oxide containing an alkali metal element and bismuth (Bi), it preferably further contain 15 mol % or less of a perovskite-structure oxide containing an alkaline earth metal element and at least one species selected from the group consisting of titanium (Ti) and zirconium (Zr). As the alkaline earth metal element, at least one species selected from the group consisting of magnesium (Mg), calcium (Ca), strontium (Sr) and barium (Ba) is preferably usable. In this case, more excellent piezoelectric characteristics can be obtained. The perovskite-structure oxide containing an alkaline earth metal element and at least one species of titanium (Ti) and zirconium (Zr) is specifically represented by chemical formula (3) above.

When the piezoelectric layer contains an oxide containing an alkali metal element and bismuth (Bi), it may further contain an oxide containing an alkali metal element and niobium (Nb) as described above. In this case, it is preferred that the content of the oxide containing an alkali metal element and niobium (Nb) is 15 mol % or less.

Incidentally, though the piezoelectric layer may contain lead (Pb), it is preferred that the content thereof is 1 mass % or less from the viewpoint of low-pollution property, ambience property and ecological property. Most preferably, the piezoelectric layer contains no lead. In a conventional multilayer piezoelectric element using lead-based piezoelectric porcelain, there has been fear that lead is discharged into the environment due to the evaporation of lead during firing or after a multilayer piezoelectric element that has been circulated in the market is disposed of. By establishing lead-free piezoelectric layers, however, it is made possible to realize multilayer piezoelectric elements extremely excellent from the standpoint of low-pollution property, ambience property and ecological property. Therefore, the range of application multilayer piezoelectric elements can be made further wider.

The piezoelectric layer comprises piezoelectric porcelain that is a sintered body has a preferable thickness of around 1 μm to around 200 μm. The number of the piezoelectric layers is determined in accordance with the displacement aimed at. Furthermore, the mean particle diameter of the crystal grains of the piezoelectric porcelain is preferably the range of 1 μm to around 50 μm.

In the multilayer piezoelectric element, described above, when the piezoelectric layer contains alkali metal element and niobium (Nb) or bismuth (Bi), since the internal electrodes are formed of base metal, there is no case where the piezoelectric characteristics are not deteriorated due to the reaction between the niobium (Nb) or bismuth (Bi) contained in the piezoelectric element and the internal electrodes to thereby acquire large displacement. In addition, the displacement can optionally be adjusted by varying the number of the piezoelectric layers. Thus, it is possible to make use of relatively inexpensive multilayer piezoelectric elements extremely excellent from the viewpoint of low-pollution property, ambience property and ecological property.

The multilayer piezoelectric element having the aforementioned configuration can be produced by the following procedure, for example.

First, paste for forming a piezoelectric layer is prepared. For example, oxides, composite oxides or compounds containing raw materials for the aforementioned chief ingredients were prepared. Powders of the raw materials for the chief ingredients are mixed so that the aforementioned ranges of contents may be satisfied, then temporarily fired and pulverized into microparticles that is added with a vehicle and kneaded. The compounds referred to herein include carbonates, sulfates, nitrates, oxalates hydroxides or organic metal compounds that will become oxides after being fired.

The vehicle includes organic vehicles and water-based vehicles and may suitably be selected in accordance with the object to be achieved. The organic vehicle has a binder dissolved in an organic solvent, and the water-based vehicle has a water-soluble binder and dispersant dissolved in water. The binder is not particularly limited and is selected for use from various kinds of binders including ethyl cellulose and polyvinyl butyral. Also, the organic solvent is not particularly limited and is selected in accordance with the formation method. When the formation method is a printing method or a sheet method, for example, the organic solvent is selected from terpineol, diethylene glycol monobutyl ether, acetone and toluene. The water-soluble binder is not particularly limited and is selected for use from polyvinyl alcohol, cellulose, water-soluble acrylic resin and emulsion.

The content of the vehicle in the paste for piezoelectric layers is not particularly limited, but generally adjusted so that the content of the binder may fall in the range of approximately 1 to 5 mass % and the content of the solvent in the range of approximately 10 to 50 mass %. In addition, the paste for the piezoelectric layers may be added, when necessary, with additives, such as dispersants or plasticizers. Desirably, the total content of the additives is 10 mass % or less.

Paste for forming internal electrodes is then produced. The paste for internal electrodes is produced by the procedure of kneading the materials for the internal electrodes, such as metallic copper and compounds that become metallic copper after being fired, with a vehicle.

The vehicle may be the same as that used for the paste for piezoelectric layers. The content of the vehicle in the paste for internal electrodes is the same as that in the paste for piezoelectric layers. The paste for internal electrodes may be added, when necessary, with additives, such as dispersants, plasticizers and piezoelectric materials. Preferably, the total content of the additives is 20 mass % or less.

Subsequently, green chips that are precursors to a multilayer body are produced by the printing method or sheet method, for example, using the paste for piezoelectric layers and paste for internal electrodes. When the printing method is used, for example, the paste for piezoelectric layers and paste for internal electrodes are alternately printed on a substrate formed of polyethylene terephthalate (hereinafter referred to as the PET substrate). The resultant body is subjected to thermocompression, then cut into prescribed shapes and exfoliated from the PET substrate to produce green chips. In the case of the sheet method, the paste for piezoelectric layers is used to form green sheets on which the paste layers for internal electrodes are printed. A plurality of the resultant bodies are stacked, subjected to thermocompression and cut into prescribed shapes to produce green chips.

The green chips thus produced are subjected to debinder treatment and then fired to form a multilayer body. The firing is performed in an atmosphere having an oxygen partial pressure desirably in the range of 1×10⁻⁷ to 1×10⁻²⁰ atm. when the internal electrodes are formed of copper (Cu). When the oxygen partial pressure is lower than the range, the alkali metal element is reduced to deteriorate the piezoelectric characteristics. When it exceeds the range, the internal electrodes tend to be oxidized.

The multilayer body thus formed is subjected to end face polishing by barrel polishing or sandblasting. On the polished end faces terminal electrodes are formed. The thickness of the terminal electrode is appropriately determined in accordance with an intended purpose and is generally in the range of approximately 10 to 50 μm. The terminal electrode can be formed through printing or transfer of paste for terminal electrodes produced similarly to the paste for internal electrodes and seizure of the printed or transferred paste, for example.

The paste for terminal electrodes contains conductive materials, glass frits and vehicles, for example. The conductive materials contain at least one species selected from the group consisting of silver (Ag), gold (Au), copper (Cu), nickel (Ni), palladium (Pd) and platinum (Pt). The vehicles may be the same as those contained in the paste for piezoelectric layers.

Examples to which the present invention is applied will be described based on experimental results.

### EXAMPLES 1 TO 6

Multilayer piezoelectric elements were fabricated using the piezoelectric porcelain represented by chemical formula (8) below. Internal electrodes containing copper (Cu) as a chief ingredient were used.
(0.995−m)(Na_{0.57}K_{0.38}Li_{0.05})NbO₃+mSrZrO₃+nBaNb₂O₆ (8)
wherein the values of m and n in each of Examples 1 to 6 and Comparative Examples 1 to 3 are shown in Table 1 below.

Prepared as the raw materials for the chief ingredients were sodium carbonate (Na₂CO₃) powder, potassium carbonate (K₂CO₃) powder, niobium oxide (Nb2O₅) powder, lithium carbonate (Li₂CO₃) powder, strontium carbonate (SrCO₃) powder, barium carbonate (BaCO₃) and zirconium oxide (ZrO₂). Also, manganese carbonate (MnCO₃) powder was prepared as the raw material for the accessory ingredient. The raw materials for the chief ingredients and accessory ingredient were thoroughly dried and then weighed out so that the chief ingredients might become the compositions shown in chemical formula (8) and Table 1 and so that the content of manganese oxide that was the accessory ingredient was 0.31 mass % based on the total content of the chief ingredients. Incidentally, the content of the accessory ingredient was determined so that the amount of the manganese carbonate powder that was the raw material for the accessory ingredient might be 0.5 mass % based on the total mass of the carbonates of the raw materials for the chief ingredients calculated in terms of oxides having C0₂ dissociated from the carbonates.

Subsequently, strontium carbonate powder and zirconium oxide were mixed in water with a ball mill, and the resultant mixture was dried and then fired at 1100° C. for two hours to produce strontium zirconate.

The strontium zirconate thus produced, raw materials for other chief ingredients and raw material for the accessory ingredient were mixed in water with a ball mill, and the resultant mixture was dried, press-molded and temporarily fired at 850 to 1000° C. for two hours. The temporarily fired body was pulverized in water with a ball mill and then dried again.

Subsequently, 5.0 parts by mass of acrylic resin, 6.5 parts by mass of mineral spirit, 4.0 parts by mass of acetone, 20.5 parts by mass of trichloroethane and 41.5 parts by mass of methylene chloride were added to and mixed with 100 parts by mass of the dried powder with a ball mill to produce paste for the piezoelectric layers.

In addition, 33 parts by mass of terpineol, 6 parts by mass of ethyl cellulose and 1 part by mass of benzotriazole were added to 60 parts by mass of copper particles and kneaded using a three-roll mill to produce paste for the internal electrodes.

Thus, the paste for piezoelectric layers, paste for internal electrodes and paste for terminal electrodes were produced. The paste for piezoelectric layers was applied onto a film substrate of PET to form a 50 μm-thick green sheet, on which the paste for internal electrodes was printed. The green sheet having the paste for internal electrode printed thereon was exfoliated from the PET substrate. Plural sheets of the green sheets were stacked, pressure-bonded and cut into prescribed size to obtain green chips. In this case, the number of the green sheets stacked was determined so that the number of piezoelectric layers sandwiched between the internal electrodes might be 20.

Subsequently, the green chips were subjected to debinder treatment and firing under the following conditions to fabricate multilayer bodies comprising sintered bodies.

Debinder treatment conditions

| | |
|---|---|
| Temperature elevation rate: | 20° C./hour |
| Retention temperature: | 300° C. |
| Retention time: | 2 hours |
| Atmosphere: | Air |

Firing conditions

| | |
|---|---|
| Temperature elevation rate: | 200° C./hour |
| Retention temperature: | 1000° C. |
| Retention time: | 4 hours |
| Cooling rate: | 200° C./hour |
| Atmosphere: | Mixed gas of nitrogen and hydrogen |
| | humidified (40° C.), oxygen partial |
| | pressure = 1 × 10⁻¹⁰ atm. |

The firing was performed in the state wherein the green chips having undergone the debinder treatment were introduced into a sagger and coated with powder having the same composition as the piezoelectric layers.

The thus fabricated multilayer body having the end faces thereof onto which paste for terminal electrodes was transferred was fired in an atmosphere of a mixed gas consisting of nitrogen gas and hydrogen gas at 600° C. for 10 minutes to form terminal electrodes. In that way, a multilayer piezoelectric element in each of Examples 1 to 6 and Comparative Examples 1 to 3 was obtained. The multilayer piezoelectric element measured 6 mm×6 mm×2 mm, the piezoelectric layer sandwiched between the internal electrodes had a thickness of 100 μm and the thickness of the internal electrode was 2 μm.

The multilayer piezoelectric element thus obtained was subjected to polarization treatment in silicone oil heated to 150° C. at electric field intensity of 5 kV/mm for 15 minutes and left standing for 24 hours. Thereafter, the displacement generated in consequence of the application of an electric field of 3 kV/mm was measured with a displacement measurement apparatus using eddy currents. In the displacement measurement apparatus, displacement of a sample in consequence of the application of a direct current was detected with a displacement sensor and a displacement detector was used to determine the displacement generated. The displacement generated, shown in Table 1 below, was obtained by dividing the measurement value by the specimen thickness and multiplying the resultant value by 100 (measurement value/specimen thickness×100).

In Comparative Examples 1 to 3, multilayer piezoelectric elements were fabricated by following the procedure as in Examples 1 to 6 except for use of Ag—Pd electrodes as the internal electrodes and use of the air atmosphere in the firing step.

Also in each of Comparative Examples 1 to 3, the displacement generated in consequence of the application of an electric field of 3 kV/mm was measured. The results thereof are shown as well in Table 1 below.

TABLE 1

| | m | n | MnO content | Internal | Displacement |
|---|---|---|---|---|---|
| | (mol) | (mol) | (mass %) | electrode | generated (%) |
| Ex. 1 | 0.000 | 0.000 | 0.31 | Cu | 0.067 |
| Ex. 2 | 0.010 | 0.000 | 0.31 | Cu | 0.073 |
| Ex. 3 | 0.050 | 0.000 | 0.31 | Cu | 0.085 |
| Ex. 4 | 0.000 | 0.005 | 0.31 | Cu | 0.071 |
| Ex. 5 | 0.010 | 0.005 | 0.31 | Cu | 0.080 |
| Ex. 6 | 0.050 | 0.005 | 0.31 | Cu | 0.087 |
| Comp. Ex. 1 | 0.000 | 0.000 | 0.31 | Ag—Pd | 0.052 |
| Comp. Ex. 2 | 0.050 | 0.000 | 0.31 | Ag—Pd | 0.061 |
| Comp. Ex. 3 | 0.050 | 0.005 | 0.31 | Ag—Pd | 0.069 |

As was clear from Table 1 above, the displacements generated in Examples 1 to 6 were larger than those in Comparative Examples 1 to 3 using Ag—Pd as the internal electrodes. It was therefore found that using Cu electrodes as the internal electrode could make the displacement generated larger.

### EXAMPLES 7TO 10

Internal electrodes containing piezoelectric porcelain represented by chemical formula (9) below and copper as chief ingredients were used to fabricate multilayer piezoelectric elements. The fabrication method was the same as that in Examples 1 to 6 except for the substitution of tantalum (Ta) for 10 mol % of niobium (Nb). As the raw material for tantalum (Ta), tantalum oxide (Ta₂O₅) powder was used. The compositions thereof were shown in Table 2 below. (0.995−m)(Na_{0.57}K_{0.38}Li_{0.05})(Nb_{0.9}Ta_{0.1})O₃+mSrZrO₃+nBa(Nb_{0.9}Ta_{0.1})₂O₆ (9)

wherein the values of m and n in each of Examples 7 to 10 and Comparative Examples 4 and 5 are shown in Table 2 below.

Multilayer piezoelectric elements as Comparative Examples 4 and 5 were also fabricated in the same manner as in Examples 7 to 10 except for using Ag—Pd electrodes as the internal electrodes and firing in air. Displacements generated when having applied an electric field of 3 kV/mm were measured in Examples 7 to 10 and Comparative Examples 4 and 5 in the same manner as in Examples 1 to 6. The results thereof are shown in Table 2 below.

TABLE 2

| | m | n | MnO content | Internal | Displacement |
|---|---|---|---|---|---|
| | (mol) | (mol) | (mass %) | electrode | generated (%) |
| Ex. 7 | 0.000 | 0.000 | 0.31 | Cu | 0.072 |
| Ex. 8 | 0.050 | 0.000 | 0.31 | Cu | 0.093 |
| Ex. 9 | 0.000 | 0.005 | 0.31 | Cu | 0.077 |
| Ex. 10 | 0.050 | 0.005 | 0.31 | Cu | 0.098 |
| Comp. Ex. 4 | 0.000 | 0.000 | 0.31 | Ag—Pd | 0.060 |
| Comp. Ex. 5 | 0.050 | 0.005 | 0.31 | Ag—Pd | 0.081 |

It was found from Table 2 above that larger values of displacements in Examples 7 to 10 than in Comparative Examples could be confirmed similarly in Examples 1 to 6 containing no tantalum (Ta) and further that by substituting tantalum (Ta) for part of niobium (Nb) the values of the displacements in Examples 7 to 10 were larger than those in Examples 1 to 6.

### EXAMPLES 11 TO 13

Multilayer piezoelectric elements were fabricated in the same manner as in Examples 1 to 6 except for using the compositions represented by chemical formula (10) below as the chief ingredients.
0.940(Na_{0.57}K_{0.38}Li_{0.05})(Nb_{0.9}Ta_{0.1})O₃+0.05SrZrO₃+0.005(M1)(Nb_{0.9}Ta_{0.1})₂O₆ (10)
wherein M1=Mg, Ca or Sr.

Multilayer piezoelectric elements as Comparative Examples 6 to 8 were also fabricated in the same manner as in Examples 11 to 13 except for using Ag—Pd electrodes as the internal electrodes and firing in air.

Displacements generated when having applied an electric field of 3 kV/mm were measured in Examples 11 to 13 and Comparative Examples 6 to 8 in the same manner as in Examples 1 to 6. The results thereof are shown in Table 3 below.

TABLE 3

| | | MnO content | Internal | Displacement |
|---|---|---|---|---|
| | M1 | (mass %) | electrode | generated (%) |
| Ex. 11 | Mg | 0.31 | Cu | 0.078 |
| Ex. 12 | Ca | 0.31 | Cu | 0.083 |
| Ex. 13 | Sr | 0.31 | Cu | 0.087 |
| Comp. Ex. 6 | Mg | 0.31 | Ag—Pd | 0.069 |
| Comp. Ex. 7 | Ca | 0.31 | Ag—Pd | 0.076 |
| Comp, Ex. 8 | Sr | 0.31 | Ag—Pd | 0.077 |

It was found from Table 3 above that Examples 11 to 13 showed larger displacements than Comparative Examples 6 to 8 and similarly in Examples 1 to 6 even when in place of barium (Ba) that is a compound of tungsten bronze structure magnesium (Mg), calcium (Ca) or strontium (Sr) that fall in the same category of alkaline earth metal elements as barium (Ba) was used.

### EXAMPLES 14 TO 20

Multilayer piezoelectric elements were fabricated in the same manner as in Examples 1 to 6 except for using the compositions represented by chemical formula (11) below as the chief ingredients.
0.940(Na_{0.57}K_{0.38}Li_{0.05})(Nb_{0.9}Ta_{0.1})O₃+0.05(M2)(M3)O₃+0.005Ba(Nb_{0.9}Ta_{0.1})₂O₆ (11)
wherein M2=Mg, Ca or Ba and M3=Ti or Zr.

As the raw material for titanium (Ti) in chemical formula (11), titanium oxide (TiO₂) was used. In addition, (M2)(M3)O₃ in chemical formula (11) beforehand prepared synthetically and pulverized was mixed with the powder of other raw materials. Though there was a case where the substance beforehand prepared synthetically was not a compound of single perovskite structure, this posed no problem insofar as a final product contained no different phase.

Multilayer piezoelectric elements as Comparative Examples 9 to 11 were also fabricated in the same manner as in Examples 14 to 20 except for using Ag—Pd electrodes as the internal electrodes and firing in air. Displacements generated when having applied an electric field of 3 kV/mm were measured in Examples 14 to 20 and Comparative Examples 9 to 11 in the same manner as in Examples 1 and 2. The results thereof are shown in Table 4 below.

TABLE 4

| | | | MnO content | Internal | Displacement |
|---|---|---|---|---|---|
| | M2 | M3 | (mass %) | electrode | generated (%) |
| Ex. 14 | Mg | Ti | 0.31 | Cu | 0.082 |
| Ex. 15 | Ca | Ti | 0.31 | Cu | 0.085 |
| Ex. 16 | Sr | Ti | 0.31 | Cu | 0.092 |
| Ex. 17 | Ba | Ti | 0.31 | Cu | 0.094 |
| Ex. 18 | Mg | Zr | 0.31 | Cu | 0.080 |
| Ex. 19 | Ca | Zr | 0.31 | Cu | 0.080 |
| Ex. 20 | Ba | Zr | 0.31 | Cu | 0.089 |
| Comp. Ex. 9 | Mg | Ti | 0.31 | Ag—Pd | 0.071 |
| Comp. Ex. 10 | Ca | Ti | 0.31 | Ag—Pd | 0.072 |
| Comp. Ex. 11 | Ba | Ti | 0.31 | Ag—Pd | 0.078 |

It was found from Table 4 above that Examples 14 to 17 using titanium (Ti) as M3 in chemical formula (11) and various alkaline earth metal components as M2 in chemical formula (11) showed larger values of displacements generated than Comparative Examples 9 to 11 and that Examples 18 to 20 using zirconium (Zr) as M3 in chemical formula (11) and various alkaline earth metal components as M2 in chemical formula (11) also showed larger values of displacements generated.

### EXAMPLE 21

A multilayer piezoelectric element was fabricated in the same manner as in Examples 1 to 6 except for using the composition represented by chemical formula (12) below as the chief ingredient.
(Na_{0.4}K_{0.1}Bi_{0.5})_{0.99}TiO₃ (12)

The composition represented by chemical formula (12) was produced by the following procedure. Specifically, as the raw materials for the chief ingredients, sodium carbonate (Na₂CO₃) powder, potassium carbonate (K₂CO₃) powder, bismuth oxide (Bi₂O₃) powder and titanium oxide (TiO₂) powder were first prepared. Also as the raw material for the accessory ingredient, manganese carbonate (MnCO₃) powder was prepared. Subsequently, the raw materials for the chief ingredients and accessory ingredient were thoroughly dried and then. weighed out so that the chief ingredients might have the compositions shown in chemical formula (12) above and Table 5 below.

These raw materials were mixed in water with a ball mill, then dried and press-molded, and subjected to temporarily fired at 750 to 1000° C. for 2 hours. The temporarily fired product was pulverized in water with a ball mill and re-dried.

A multilayer piezoelectric element as Comparative Example 12 was fabricated in the same manner as in Example 21 except for using Ag—Pd electrodes as the internal electrodes and firing in air.

Displacements generated when having applied an electric field of 3 kV/mm were measured in Example 21 and Comparative Example 12 in the same manner as in Examples 1 to 6. The results thereof are shown in Table 5 below.

TABLE 5

| | | Internal | Displacement |
|---|---|---|---|
| | Composition | electrode | generated (%) |
| Ex. 21 | (Na_{0.4}K_{0.1}Bi_{0.5})_{0.99}TiO₃ | Cu | 0.016 |
| Comp. Ex. 12 | (Na_{0.4}K_{0.1}Bi_{0.5})_{0.99}TiO₃ | Ag—Pd | 0.009 |

It was found that use of the perovskite-structure oxide containing the alkali metal elements and bismuth (Bi) together with the internal electrode formed of Cu in Example 21 enabled the generated displacement to be made greater as in the case of the perovskite-structure oxide containing the alkali metal element and niobium (Nb).

The present invention has been described citing the embodiment and Examples. Please note, however, that the present invention is not restricted to the foregoing embodiment and Examples, but may be modified variously without departing from the scope of the appended claims.

What is claimed is:

1. A multilayer piezoelectric element comprising:
a plurality of piezoelectric layers each formed of an oxide containing an alkali metal element and niobium or bismuth; and
a plurality of internal electrodes each formed of a base metal;
said layers and said electrodes being alternately stacked.

2. A multilayer piezoelectric element according to claim 1, wherein the internal electrodes are formed of copper or copper alloy.

3. A multilayer piezoelectric element according to claim 1, wherein the oxide contains an alkali metal element and niobium and the alkali metal element comprises sodium, potassium and lithium.

4. A multilayer piezoelectric element according to claim 3, wherein the niobium has tantalum substituted for part thereof accounting for 15 mol % or less.

5. A multilayer piezoelectric element according to claim 3, wherein the oxide that contains an alkali metal element and niobium is a perovskite-structure oxide.

6. A multilayer piezoelectric element according to claim 3, wherein the piezoelectric layers contain 1 mol % or less of a tungsten bronze-structure oxide containing an alkaline earth metal element and niobium.

7. A multilayer piezoelectric element according to claim 6, wherein the piezoelectric layers contain 15 mol % or less of a perovskite-structure oxide containing an alkaline earth metal element and at least one species selected from the group consisting of titanium and zirconium.

8. A multilayer piezoelectric element according to claim 1, wherein the oxide contains an alkali metal element and bismuth and the alkali metal element comprises at least one species selected from the group consisting of sodium and potassium.

9. A multilayer piezoelectric element according to claim 8, wherein the oxide that contains an alkali metal element and bismuth is a perovskite-structure oxide.

10. A multilayer piezoelectric element according to claim 8, wherein the piezoelectric layers contain 15 mol % or less of a perovskite-structure oxide containing an alkaline earth metal element and at least one species selected from the group consisting of titanium and zirconium.

11. A multilayer piezoelectric element according to claim 8, wherein the piezoelectric layers contain 15 mol % or less of an oxide containing an alkali metal element and niobium.
